(19) United States
(12) Patent Application Publication
(10) Pub. No.: US 2025/0160187 A1
(43) Pub. Date: May 15, 2025

(54) DISPLAY DEVICE, MANUFACTURING METHOD THEREOF, AND VEHICLE HAVING DISPLAY DEVICE

(71) Applicant: Samsung Display Co., LTD., Yongin-si (KR)

(72) Inventors: BYOUNGSANG SONG, Yongin-si (KR); Hyun Eok SHIN, Yongin-si (KR)

(73) Assignee: Samsung Display Co., LTD., Yongin-si (KR)

(21) Appl. No.: 18/769,960

(22) Filed: Jul. 11, 2024

(30) Foreign Application Priority Data
Nov. 9, 2023 (KR) 10-2023-0154465

(51) Int. Cl. H10K 59/80; B60K 35/22; H10K 59/12; H10K 59/122

(52) U.S. Cl. CPC H10K 59/8792; H10K 59/1201; H10K 59/122; B60K 35/22; B60K 2360/25; B60K 2360/332

(57) ABSTRACT

According to embodiments, a display device includes a light emitting diode disposed on a substrate and including a light emitting layer, a pixel defining layer having an opening corresponding to the light emitting layer, a plurality of light blocking linear patterns disposed on the pixel defining layer and the light emitting layer and extending in a direction, an upper transparent organic layer disposed between adjacent ones of the plurality of light blocking linear patterns, and an upper transparent layer disposed on the upper transparent organic layer and having a plurality of holes overlapping the upper transparent organic layer.

### CROSS-REFERENCE TO RELATED APPLICATION

This application claims priority to and the benefit of Korean Patent Application No. 10-2023-0154465 under 35 U.S.C. § 119, filed at the Korean Intellectual Property Office (KIPO) on Nov. 9, 2023, the entire contents of which are incorporated herein by reference.

### BACKGROUND

### 1. Technical Field

The disclosure relates to a display device, a method of manufacturing the same, and a vehicle including the display device, and more specifically, to a display device including an upper transparent layer including one or more light blocking linear patterns and holes on the front surface, a method of manufacturing the same.

### 2. Description of the Related Art

A display device is a device that displays a screen and includes a liquid crystal display (LCD) and an organic light emitting diode (OLED).

These display devices are used in various electronic devices such as mobile phones, navigation devices, digital cameras, electronic books, portable game consoles, and other terminals.

Display devices can be used in a variety of fields other than electronic devices, and in the case of vehicles, a direction is being developed to digitally display conventional analog instrument clusters and center fascias using display devices.

### SUMMARY

Embodiments are intended to block light emitted from a display device from being emitted in a specific direction.

Embodiments are intended to allow gas to be discharged from the upper transparent organic layer disposed between the light blocking linear patterns that limit the direction of light emitted from the display device.

This is to ensure that the light emitted from the display device used in the vehicle is provided to the driver's eyes and does not interfere with driving.

This is to prevent the display device used in a vehicle from reflecting on the windshield of the vehicle at night and blocking the driver's view.

A display device according to an embodiment includes a light emitting diode disposed on a substrate and including a light emitting layer, a pixel defining layer having an opening corresponding to the light emitting layer, a plurality of light blocking linear patterns disposed on top of the pixel defining layer and the light emitting layer and extending in a direction, an upper transparent organic layer disposed between adjacent ones of the plurality of light blocking linear patterns, and an upper transparent layer above the upper transparent organic layer and having a plurality of holes overlapping with the upper transparent organic layer.

A plurality of grooves may be formed on the upper surface of the upper transparent organic layer at positions corresponding to each of the plurality of holes.

Each of the plurality of grooves may have an undercut structure and be formed larger than each of the plurality of holes.

The upper transparent layer may be formed of transparent conductive oxide.

Each of the plurality of light blocking linear patterns may have a height of about 20 μm or more and about 50 μm or less, and a width of about 1 μm or more and about 7 μm or less, and each of the plurality of grooves may have a depth of about 0.9 μm or more and about 10 μm or less.

The plurality of holes may have an area ratio in a range of about 10% to about 20% of a total area.

At least one of the plurality of light blocking linear patterns may cross the light emitting layer and overlap the light emitting layer.

The upper transparent layer and the upper transparent organic layer may not overlap the plurality of light blocking linear patterns.

A method of manufacturing a display device according to an embodiment includes sequentially forming an upper transparent organic layer and an upper transparent layer on a substrate having an encapsulation layer, forming a plurality of holes by etching the upper transparent layer, forming a hard mask on the upper transparent layer, forming a photoresist pattern on the hard mask and removing exposed the hard mask, the upper transparent layer, and the upper transparent organic layer using the photoresist pattern as a mask to form a portion where a light blocking linear pattern is to be formed, applying a light blocking organic material containing a black pigment, and removing the photoresist pattern and the light blocking organic material applied on a top portion, and removing the hard mask to complete the light blocking linear pattern.

The forming the plurality of holes may include etching the upper transparent organic layer exposed by the plurality of holes of the upper transparent layer together to form a plurality of grooves on an upper surface of the upper transparent organic layer.

Each of the plurality of grooves may have an undercut structure and may be formed larger than each of the plurality of holes.

Each of the plurality of grooves may be formed as deeper than a thickness of the hard mask by at least about 0.1 μm and no more than about 5 μm.

The light blocking linear pattern may have a height of about 20 μm or more and about 50 μm or less, and a width of about 1 μm or more and about 7 μm or less, and each of the plurality of grooves may have a depth of about 0.9 μm or more and about 10 μm or less.

The plurality of holes may have an area ratio in a range of about 10% to about 20% of a total area.

According to an embodiment, a vehicle includes a first light emitting display device, wherein the first light emitting display device includes a light emitting diode disposed on a substrate and including a light emitting layer, a pixel defining layer having an opening corresponding to the light emitting layer, a plurality of first light blocking linear patterns disposed on top of the pixel defining layer and the light emitting layer and extending in a first direction, an upper transparent organic layer disposed between adjacent ones of the plurality of first light blocking linear patterns, and an upper transparent layer disposed on the upper transparent organic layer and having a plurality of holes overlapping with the upper transparent organic layer.

The vehicle further includes a second light emitting display device, wherein the second light emitting display device includes a light emitting diode disposed on a substrate and including a light emitting layer, a pixel defining layer having an opening corresponding to the light emitting layer, and a plurality of second light blocking linear patterns disposed on top of the pixel defining layer and the light emitting layer and extending in a second direction different from the first direction, an upper transparent organic layer disposed between adjacent ones of the plurality of second light blocking linear patterns, and an upper transparent layer disposed on the upper transparent organic layer and having a plurality of holes overlapping the upper transparent organic layer.

A plurality of grooves may be formed on the upper surface of the upper transparent organic layer at positions corresponding to each of the plurality of holes.

Each of the plurality of grooves may have an undercut structure and may be formed larger than each of the plurality of holes.

The upper transparent layer may be formed of transparent conductive oxide.

Each of the plurality of first light blocking linear patterns or each of the plurality of second light blocking linear patterns may have a height of about 20 μm or more and about 50 μm or less, and a width of about 1 μm or more and about 7 μm or less, and each of the plurality of grooves may have a depth of about 0.9 μm or more and about 10 μm or less, and the plurality of holes may have an area ratio in a range of about 10% to about 20% of a total area.

According to embodiments, a plurality of light blocking linear patterns may be formed on the entire surface in a direction so that light provided from the light emitting layer is not emitted in a specific direction.

The embodiments are intended to prevent delamination problems caused by gas by forming holes in the upper transparent layer disposed on the upper transparent organic layer, which is disposed between the light blocking linear patterns that limit the direction of light emitted from the display device, so that gas can be discharged from the upper transparent organic layer.

By preventing the light emitted from the display device used in the vehicle from being provided to the vehicle's windshield, light may not be reflected from the vehicle's windshield at night and may not interfere with the driver's vision.

The light emitted from the display device disposed on the passenger seat may not be provided to the driver, so it may not interfere with driving.

Compared to the comparative example in which the light blocking linear pattern is formed in the form of a film on the front surface, the embodiment is formed directly within the light emitting display device, so there is no problem of misalignment, the moiré phenomenon can be eliminated, the thickness may be thin, the manufacturing cost may be reduced, and it can also have the advantage of high transmittance.

The technical objectives to be achieved by the disclosure are not limited to those described herein, and other technical objectives that are not mentioned herein would be clearly understood by a person skilled in the art from the description of the disclosure.

### BRIEF DESCRIPTION OF THE DRAWINGS

FIG. 1 is a plan view schematically showing a pixel of a light emitting display device according to an embodiment.

FIG. 2 is a plan view schematically showing light blocking linear patterns and an upper transparent organic layer formed in a light emitting display device according to an embodiment.

FIG. 3 is a plan view schematically showing a light emitting display device combining FIG. 1 and FIG. 2.

FIG. 4 is a schematic cross-sectional view taken along line IV-IV′ of FIG. 3.

FIG. 5 is a schematic cross-sectional view of a light emitting display device according to another embodiment.

FIG. 6 to FIG. 11 are schematic diagrams sequentially showing a manufacturing method for forming a light blocking linear pattern and an upper transparent layer of a light emitting display device according to an embodiment.

FIG. 12 is a schematic diagram illustrating a case where a light emitting display device according to a comparative example is applied to a vehicle.

FIG. 13 is a schematic diagram illustrating a case where a light emitting display device according to an embodiment is applied to a vehicle.

FIG. 14 is a schematic diagram illustrating a case where a light emitting display device is applied to a vehicle according to another embodiment.

FIG. 15 is a schematic diagram illustrating a cross-sectional structure of a light emitting display device according to an embodiment.

### DETAILED DESCRIPTION OF THE EMBODIMENTS

Hereinafter, with reference to the attached drawings, various embodiments will be described in detail so that those skilled in the art can easily implement the disclosure.

The disclosure may be implemented in many different forms and is not limited to the embodiments described herein.

In order to clearly explain the disclosure, parts that are not relevant to the description may be omitted, and identical or similar components are assigned the same reference numerals throughout the specification.

The size and thickness of each component shown in the drawings may be shown arbitrarily for convenience of explanation, so the disclosure is not necessarily limited to that which is shown.

In the drawings, the thickness may be enlarged to clearly express various layers and areas.

In the drawings, for convenience of explanation, the thicknesses of some layers and regions may be exaggerated.

Additionally, when a part, such as a layer, membrane, region, plate, or component is said to be “above” or “on” another part, this means not only when it is “directly above” another part, but also when there is another part in between.

Conversely, when a part is said to be “right on top” or “directly on top” of another part, it means that there is no other part in between.

Being “above” or “on” a reference part means being disposed above or below the reference part, and does not necessarily mean being disposed “above” or “on” it in the direction opposite to gravity.

Throughout the specification, when a part is said to “include,” “comprise,” or “have” a certain component, this means that it may further include other components rather than excluding other components, unless specifically stated to the contrary.

Throughout the specification, when reference is made to “in a plan view” or “on a plane,” this means when the target portion is viewed from above, and when reference is made to “in cross-section,” this means when a cross-section of the target portion is cut vertically and viewed from the side.

Throughout the specification, when “connected” is used, this does not mean only when two or more components are directly connected, but when two or more components are indirectly connected through other components, they are physically connected, this may include not only the case of being connected or electrically connected, but also the case where parts which are referred to by different names depending on location or function are substantially connected to each other.

Throughout the specification, when a portion such as a wiring, layer, film, region, plate, or component is said to “extend in the first or second direction,” it does not only mean a straight line extending in that direction, but also a structure that extends overall in the first or second direction, including a structure that is bent at some part, has a zigzag structure, or extends with a curved structure.

Electronic devices (e.g., mobile phones, TVs, monitors, laptop computers, etc.) containing display devices, display panels, etc. described in the specification, or display devices, display panels, etc. manufactured by the manufacturing method described in the specification are not excluded from the scope of rights of this specification.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

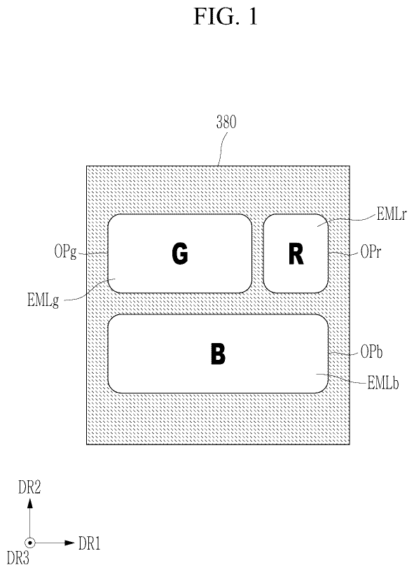

Hereinafter, a light blocking linear pattern formed in a light emitting display device according to an embodiment will be described through FIG. 1 to FIG. 4.

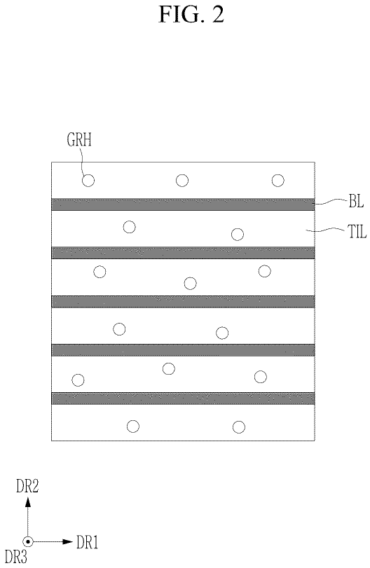

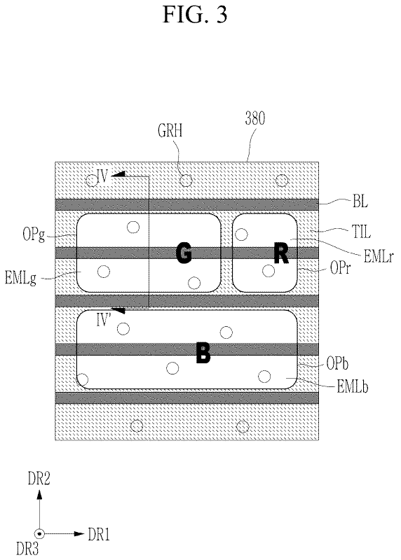

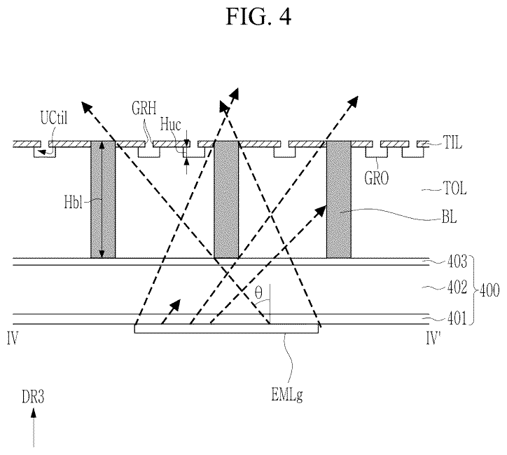

FIG. 1 is a plan view schematically showing a pixel of a light emitting display device according to an embodiment, and FIG. 2 is a plan view schematically showing light blocking linear patterns and an upper transparent organic layer formed in the light emitting display device according to an embodiment, FIG. 3 is a plan view schematically showing a light emitting display device combining FIG. 1 and FIG. 2, and FIG. 4 is a schematic cross-sectional view taken along line IV-IV′ of FIG. 3.

In FIG. 1, three light emitting diodes representing different colors (R, G, and B) disposed adjacent to each other are briefly shown, and each light emitting diode may include light emitting layers EMLr, EMLg, EMLb.

Each light emitting layer EMLr, EMLg, EMLb may be a part of the light emitting diode that emits light, and may be partitioned by the pixel defining layer 380.

Each light emitting layer EMLr, EMLg, EMLb may have a structure that overlaps the pixel defining layer opening OPr, OPg, OPb disposed in the pixel defining layer 380, and at least a portion of each light emitting layers EMLr, EMLg, EMLb may have a structure that is exposed to the top without overlapping the pixel defining layer 380.

Depending on the embodiment, each light emitting layer EMLr, EMLg, EMLb may be disposed only within each opening OPr, OPg, OPb of the pixel defining layer 380.

Although not shown in FIG. 1, a cathode and an encapsulation layer may be disposed on the pixel defining layer 380 and the light emitting layers EMLr, EMLg, EMLb, and an anode may be disposed below each light emitting layer EMLr, EMLg, EMLb.

Here, an anode, a light emitting layer EMLr, EMLg, EMLb, and the cathode may constitute a light emitting diode.

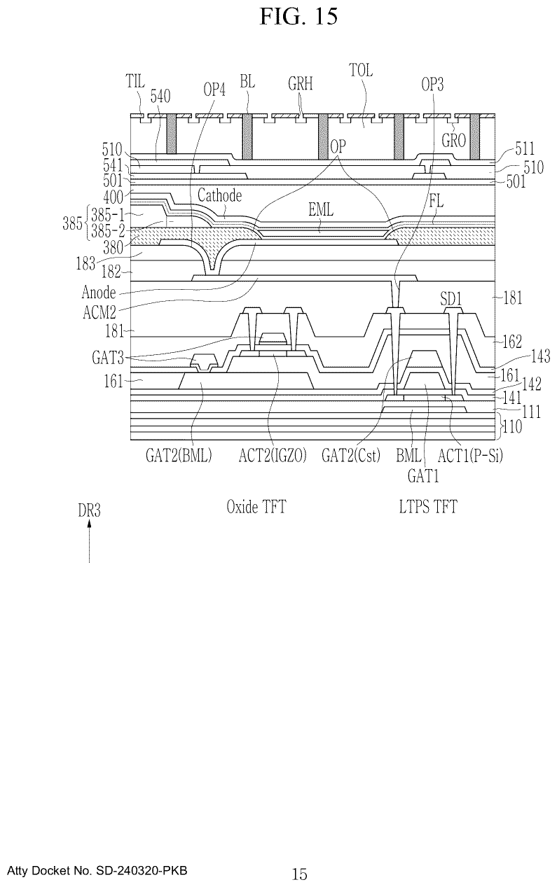

The detailed stacked structure of the light emitting diode will be described through FIG. 15.

FIG. 2 shows a planar structure of light blocking linear patterns BL disposed on top of the light emitting diode, an upper transparent layer TIL disposed around the light emitting diode, and holes GRH disposed in the upper transparent layer TIL.

Referring to FIG. 4, an upper transparent organic layer TOL may be disposed below the upper transparent layer TIL.

The light blocking linear patterns BL may extend in a direction and may be arranged such that the distance between adjacent light blocking linear patterns BL is constant.

Depending on the embodiment, the spacing between the light blocking linear patterns BL may not be constant.

An upper transparent layer TIL may be disposed in an area where the light blocking linear patterns BL are not formed, and referring to FIG. 4, an upper transparent organic layer TOL may be disposed below the upper transparent layer TIL.

It may have a structure in which light blocking linear patterns BL are formed within openings formed in the upper transparent layer TIL and the upper transparent organic layer TOL.

Holes GRH may be disposed in the upper transparent layer TIL.

The hole GRH may expose the upper transparent organic layer TOL and may allow gas generated in the upper transparent organic layer TOL to be discharged without being blocked by the upper transparent layer TIL.

The size of each hole GRH may be formed in various ways, and for gas discharge, the total area of the holes GRH may be formed at an area ratio in a range of about 10% to about 20% of the total area, and in an embodiment, the total area of the holes GRH is in a range of about 10% to about 20% of the total area. GRH can be formed with an area ratio of about 15% to facilitate gas discharge from the upper transparent organic layer TOL.

In FIG. 2, the hole GRH is shown as a circle, but it can be formed in various planar shapes such as oval, triangle, and square in addition to the circle.

Although not shown in FIG. 2, referring to FIG. 4, depending on the embodiment, the upper transparent organic layer TOL of the portion where the hole GRH is disposed may have a groove (see GRO in FIG. 4) having an undercut (see UCtil in FIG. 4) structure.

The upper transparent layer TIL and the upper transparent organic layer TOL may be disposed in an area where the light blocking linear pattern BL is not formed and may not overlap the light blocking linear pattern BL in a plan view.

An embodiment of a structure with a light emitting diode having an arrangement like FIG. 1, and multiple light blocking linear patterns BL and an upper transparent organic layer TOL as in FIG. 2, is shown in FIG. 3.

In the embodiment of FIG. 3, a light blocking linear pattern BL may be arranged to have a structure crossing between one light emitting diode, on both sides of the light emitting diode, and also between adjacent light emitting diodes. It has a structure in which linear patterns BL are arranged.

For example, each light emitting layer EMLr, EMLg, EMLb and/or the openings OPr, OPg, OPb of the pixel defining layer 380 may overlap a light blocking linear pattern BL, and may have a structure in which a light blocking linear pattern BL passes through the center of each light emitting layer EMLr, EMLg, EMLb and/or the openings OPr, OPg, OPb of the pixel defining layer 380.

Each light emitting layer EMLr, EMLg, EMLb and/or the opening OPr, OPg, OPb of the pixel defining layer 380 may have a pair of light blocking linear patterns BL that do not overlap but are disposed adjacent to each other, and the light blocking linear pattern BL may have a structure that overlaps the pixel defining layer 380.

The cross-sectional line IV-IV′ in FIG. 3 is formed around the green-light emitting layer EMLg, and the cross-sectional structure of FIG. 4 will be described in detail based on the green-light emitting layer EMLg.

In FIG. 4, only the light emitting layer EMLg is briefly shown, and the anode and cathode that may be disposed above and below the light emitting layer EMLg are omitted.

In case that a light emitting diode emits light, it emits light from the light emitting layer EMLg, and the light emitted from the light emitting layer EMLg can be emitted in various directions.

However, due to the light blocking linear pattern BL disposed on the top of the light emitting layer EMLg, light may not be transmitted at an angle exceeding a certain angle.

As a result, the viewing angle of the light emitting display device may not be limited.

The viewing angle of the light emitting display device may be determined according to the distance between the light blocking linear pattern BL and the light emitting layer EMLg, the spacing between adjacent light blocking linear patterns BL, and the width and height of the light blocking linear pattern BL, and the following describes the characteristics of the light blocking linear pattern BL according to this embodiment.

The light blocking linear pattern BL may be formed of a material capable of blocking light and may be formed of the same material as a light blocking layer (black matrix) used in a light emitting display device. In other words, the light blocking linear pattern BL and the light blocking layer may include a same material.

The light blocking linear pattern BL may be formed of an organic material containing black pigment.

Referring to FIG. 4, the light blocking linear pattern BL may have a pillar shape and a structure with a constant width. However, depending on the embodiment, the width may vary depending on the height, and the width may be thicker in the middle or thicker at the top or bottom.

The upper surface of the light blocking linear pattern BL may be formed flat, but depending on the embodiment, the upper surface of the light blocking linear pattern BL may be etched during the process and may not be flat but have concave or convex portions.

The light blocking linear pattern BL according to the embodiment of FIG. 4 may be formed thicker than the upper transparent organic layer TOL and thus may be taller, and may have a height that is the sum of the thicknesses of the upper transparent layer TIL and the upper transparent organic layer TOL.

For example, the top surface of the light blocking linear pattern BL may be disposed higher than the top surface of the upper transparent organic layer TOL and may be disposed farther from the substrate.

The light blocking linear pattern BL may serve to block the light emitted from the light emitting layer EMLg from being emitted beyond a certain angle (θ; hereinafter referred to as the viewing angle) relative to the normal. To this end, the light blocking linear pattern BL may be used to have a relatively large height.

The height Hbl of the light blocking linear pattern BL according to an embodiment may be formed to be in a range of about 20 μm or more and about 50 μm or less, and in an embodiment, the height Hbl may be formed to be about 31 μm.

The width of the light blocking linear pattern BL in FIG. 4 may be in a range of about 1 μm or more and about 7 μm or less, and in an embodiment, it may be formed to be about 4 μm.

For example, in order to prevent light from being provided beyond a certain angle (θ) relative to the normal, the light blocking linear pattern BL may be formed higher than the width, and the ratio of the height to the width may be about 4 or more and about 50 or less.

The spacing between the light blocking linear patterns BL may be determined based on the angle at which light is provided, and depending on the embodiment, the spacing between adjacent light blocking linear patterns BL may have a value smaller than the height of the light blocking linear patterns BL. It can have a value of about 5 μm or more and about 20 μm or less.

In this example, the gap between adjacent light blocking linear patterns BL was set to about 13 μm.

As the spacing between the light blocking linear patterns BL gets closer, the blocked viewing angle (θ) may decrease, so the blocking effect increases, but there may be a disadvantage in that transmittance may decrease.

Therefore, it may be desirable to consider both the transmittance and the blocked viewing angle (θ), and in an embodiment, the blocked viewing angle (θ) can be set to about 30 degrees with a transmittance of about 80%.

In an embodiment in which the transmittance can be further reduced, the blocked viewing angle (θ) can be reduced to up to about 15 degrees.

In embodiments where the transmittance must be high or the blocked viewing angle (θ) may be greater than about 30 degrees, light can be set so as not to proceed at various angles, and the blocked viewing angle (θ) can be set to an angle of about 45 degrees.

An upper transparent organic layer TOL and an upper transparent layer TIL may be disposed between the light blocking linear patterns BL.

The upper transparent organic layer TOL may be formed using a transparent organic material having a low refractive index, and may be a low-temperature transparent organic layer that does not use a high-temperature process when forming the upper transparent organic layer TOL.

A variety of materials may be used as the transparent organic material, and the low refractive index used in an embodiment may be about 1.46.

The thickness of the upper transparent organic layer TOL may have a thickness equivalent to the height of the light blocking linear pattern BL, but according to the embodiment of FIG. 4, the upper transparent layer TIL may be thinner than the height of the light blocking linear pattern BL.

One or more grooves GRO may be formed on the upper surface of the upper transparent organic layer TOL, and the grooves GRO may be disposed at positions corresponding to the holes GRH of the subsequently formed upper transparent layer TIL.

The size of the groove GRO may be larger than the hole GRH in the upper transparent layer TIL.

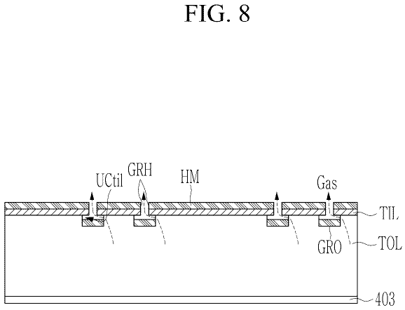

The depth Huc of the groove GRO may be formed deeper than the thickness of the hard mask (see HM in FIG. 8) formed in the subsequent process.

In an embodiment, the groove GRO may be formed deeper than the thickness of the hard mask by about 0.1 μm or more and about 5 μm or less, and the groove GRO may have a depth of about 0.9 μm or more and about 10 μm or less.

An upper transparent layer TIL may be further disposed on the upper transparent organic layer TOL, and one or more holes GRH may be formed in the upper transparent layer TIL.

The area of each hole GRH may vary, and when considering gas emissions, the individual area of each hole GRH may not be important, but the entire holes GRH may be important.

The total area of the holes GRH according to the embodiment may have an area ratio in a range of about 10% to about 20% of the total area.

For example, the holes GRH each expose the upper transparent organic layer TOL, and allow gas generated in the upper transparent organic layer TOL to be discharged without being blocked by the upper transparent layer TIL.

More specifically, the process of forming a hole GRH to discharge gas generated from the upper transparent organic layer TOL may be as follows.

In order to form a high light blocking linear pattern BL, the upper transparent organic layer TOL may be formed thick, then a hard mask (see HM in FIG. 8) may be formed, and the upper transparent organic layer TOL may be etched according to the pattern of the hard mask, and a light blocking linear pattern BL may be formed on the removed upper transparent organic layer TOL.

Generally, the upper transparent organic layer TOL may be formed through a low-temperature process, but in case that a hard mask is deposited on the top, the temperature rises and gas may be generated from the upper transparent organic layer TOL.

If gas is not discharged, a problem may occur in which the layer disposed on top of the upper transparent organic layer TOL (upper transparent layer TIL) is lifted due to the gas.

To solve this film lifting problem, gas discharge may be required, and in this embodiment, one or more holes GRH are formed in the upper transparent layer TIL.

The upper transparent layer TIL may have a structure that contacts a side surface of a portion of the light blocking linear pattern BL, and may have a structure that does not overlap the light blocking linear pattern BL in a plan view.

However, depending on the embodiment, the upper transparent layer TIL may overlap a portion of the light blocking linear pattern BL in a plan view.

The upper transparent layer TIL may be formed of transparent conductive oxide TCO, and the transparent conductive oxide TCO may be formed of, e.g., ITO, IZO, or IGZO.

Considering the etch ratio in the subsequent process, the upper transparent layer TIL may be formed of IZO or IGZO rather than ITO.

Depending on the embodiment, an additional insulating layer may be disposed on the upper transparent layer TIL and the light blocking linear pattern BL, and/or a polarizer may be attached to the upper transparent layer TIL and the light blocking linear pattern BL using an adhesive.

In FIG. 4, an encapsulation layer 400 is disposed below the upper transparent organic layer TOL and the light blocking linear pattern BL, and the encapsulation layer 400 may include a lower inorganic encapsulation layer 401, an organic encapsulation layer 402, and an upper inorganic encapsulation layer 403.

A light emitting diode is disposed below the encapsulation layer 400, and only the light emitting layer EMLg is briefly shown in FIG. 4.

The specific substructure is described through FIG. 15.

Depending on the embodiment, a sensing insulating layer and one or more sensing electrodes may be disposed between the upper transparent layer TIL and the encapsulation layer 400 to detect a touch.

The structure for detecting touch will also be described through FIG. 15, which will be described below.

As described above, the embodiment in which the light blocking linear pattern BL is formed within the light emitting display device may differ from the comparative example in which the viewing angle is reduced by attaching a film to the front of the light emitting display device in the following respects.

Firstly, when attaching a film, there may be problems with misalignment, and the moiré phenomenon may occur if it is not attached properly. However, in this embodiment, there are no alignment problems, and moiré can be readily removed by adjusting the spacing of the light blocking linear pattern BL.

The comparative example of attaching a film may have the disadvantage that manufacturing cost increases and transmittance is reduced due to light loss occurring at the interface due to an adhesive, etc. during attachment.

Referring to FIG. 3 and FIG. 4, some of the light blocking linear patterns BL may overlap the light emitting diodes or light emitting layers EMLr, EMLg, EMLb, and others may overlap the pixel defining layer 380.

In the embodiments of FIG. 3 and FIG. 4, each light emitting layer EMLr, EMLg, EMLb may overlap a light blocking linear pattern BL, but the number and position of the overlapping light blocking linear patterns BL may vary.

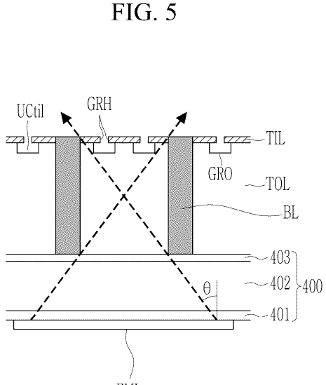

An embodiment of various arrangements of the openings OPr, OPg, OPb and light blocking linear patterns BL of each light emitting layer EMLr, EMLg, EMLb and/or the pixel defining layer 380 will be described through FIG. 5.

FIG. 5 is a schematic cross-sectional view of a light emitting display device according to another embodiment.

The embodiment of FIG. 5, unlike the embodiment of FIG. 3 and FIG. 4, may be an embodiment in which a light emitting layer EMLg overlaps two light blocking linear patterns BL.

As shown in FIG. 5, even if the two light blocking linear patterns BL and the light emitting layer EMLg overlap, if the height and spacing of the light blocking linear patterns BL are the same, the blocked viewing angle θ may be the same.

In FIG. 3 to FIG. 5, the light blocking linear pattern BL has a structure in which the light blocking linear pattern BL passes through the center of the light emitting layer EMLg or is disposed at a position symmetrical with respect to the center line.

However, depending on the embodiment, the light blocking linear pattern BL may be formed at a position that is not symmetrical with respect to the center line without passing through the center of the light emitting layer EMLg.

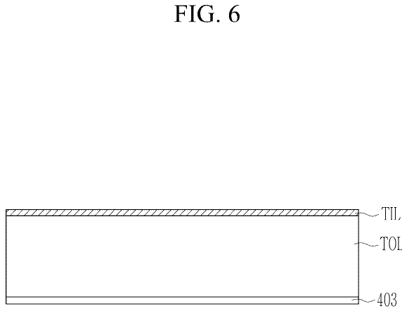

Hereinafter, a manufacturing method for forming a light blocking linear pattern according to an embodiment will be described in detail through FIG. 6 to FIG. 11.

FIG. 6 to FIG. 11 are diagrams sequentially showing a manufacturing method for forming a light blocking linear pattern and an upper transparent layer of a light emitting display device according to an embodiment.

In FIG. 6 to FIG. 11, only some of the lower layers are shown, and in FIG. 6 to FIG. 11 only the upper inorganic encapsulation layer 403 included in the encapsulation layer 400 is shown.

Referring to FIG. 6, an upper transparent organic layer TOL and an upper transparent layer TIL may be continuously formed on the upper inorganic encapsulation layer 403.

Here, the upper transparent organic layer TOL may be formed of a transparent organic material with a low refractive index, and various transparent organic materials having a refractive index of about 1.46 may be used as the low refractive index transparent organic material.

The upper transparent organic layer TOL may be a low-temperature transparent organic layer that does not use a high-temperature process when laminated.

The material for the upper transparent organic layer TOL may be laminated to a thickness corresponding to the height of the light blocking linear pattern BL to be formed later, and may be formed to be about 20 μm or more and about 50 μm or less.

The upper transparent layer TIL may be formed of a transparent conductive oxide TCO such as IZO or IGZO.

Here, the material for the upper transparent layer TIL may be formed of IZO of about 300 Å or more and about 1000 Å, and in this example, it was formed of IZO of about 500 Å.

IZO and IGZO have transparent characteristics and have excellent selectivity during dry etching, so they can serve as an etch stopper for dry etching.

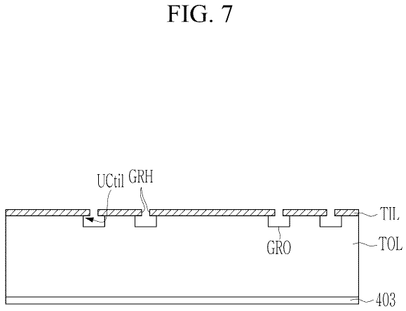

Thereafter, as shown in FIG. 7, the upper transparent layer TIL may be etched to form holes GRH.

The hole GRH may be formed by isotropic dry etching, and the upper transparent organic layer TOL exposed by the hole GRH may be etched to form a groove GRO on the upper surface.

The holes GRH may be formed through exposure using a mask to form a photoresist pattern (not shown) on the top of the upper transparent layer TIL, and then through dry etching or wet etching.

The hole GRH of the upper transparent layer TIL may have a one-to-one correspondence with the groove GRO of the upper transparent organic layer TOL, and the groove GRO may have an undercut Uctil structure.

Due to the undercut Uctil structure, a portion of the groove GRO may be covered with the upper transparent layer TIL, and the size of the groove GRO may be larger than the hole GRH in the upper transparent layer TIL.

The depth of the groove GRO may be formed deeper than the thickness of the hard mask (see HM in FIG. 8) formed in the subsequent process.

In an embodiment, the groove GRO may be formed deeper than the thickness of the hard mask by about 0.1 μm or more and about 5 μm or less, and the groove GRO may have a depth of about 0.9 μm or more and about 10 μm or less.

Afterwards, as shown in FIG. 8, a hard mask HM may be formed on the upper transparent layer TIL.

The hard mask HM may be formed of (or include) a metal such as aluminum (Al) or molybdenum (Mo) or an alloy thereof, and in this embodiment, it is formed of aluminum (Al).

The hard mask HM may be formed in the groove GRO of the upper transparent organic layer TOL through the hole GRH of the upper transparent layer TIL, but the depth of the groove GRO may be deeper than the thickness of the hard mask HM, so that the hard mask HM may have a structure separated from the upper transparent layer TIL.

In this embodiment, the hard mask HM may be formed to be about 8000 Å, and in this case, the groove GRO may be about 1.3 μm.

Since the hard mask HM may be disposed away from the upper transparent layer TIL within the groove GRO of the upper transparent organic layer TOL, a portion of the side wall of the upper transparent organic layer TOL may be exposed without being covered by the hard mask HM, and the gas of the upper transparent organic layer TOL can be discharged through this part.

Specifically, the upper transparent organic layer TOL may be formed through a low-temperature process, but in case that a hard mask is deposited on the top, the temperature may rise and gas may be generated from the upper transparent organic layer TOL.

The generated gas may be discharged through a portion of the sidewall of the upper transparent organic layer TOL that is not covered by the hard mask HM, and may be discharged to the outside through the hole GRH of the upper transparent layer TIL.

As a result, the problem of the upper transparent layer TIL being lifted due to gas may not occur.

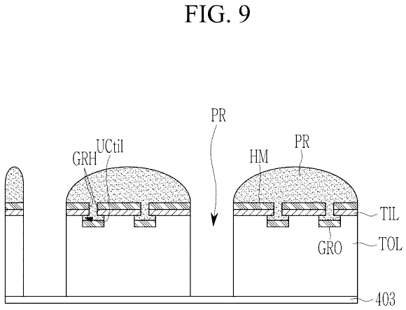

Then, as shown in FIG. 9, after forming the photoresist pattern PR on the hard mask HM, the hard mask HM, the upper transparent layer TIL, and the like may be exposed using the photoresist pattern PR as a mask, and the upper transparent organic layer TOL may be removed to form a portion where the light blocking linear pattern BL will be formed.

Specifically, the photo resist pattern PR can be formed by exposing the hard mask HM using a separate mask, and the hard mask HM and upper transparent layer TIL may be exposed based on the formed photo resist pattern PR, and the upper transparent organic layer TOL can be removed through anisotropic dry etching.

Here, the removed hard mask HM, the upper transparent layer TIL, and the upper transparent organic layer TOL may be formed in a structure extending in a direction.

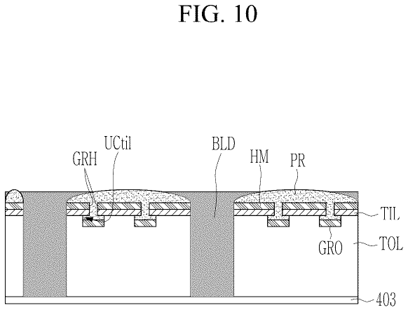

Thereafter, as shown in FIG. 10, above the photoresist pattern PR, and in the area where the hard mask HM, the upper transparent layer TIL, and the upper transparent organic layer TOL were removed (the removed area is where the light blocking linear pattern BL will be formed), an organic material containing a black pigment (BLD; hereinafter also referred to as a light blocking organic material) may be applied to the area to be formed.

Comparing FIG. 9 and FIG. 10, it can be seen that the thickness of the photoresist pattern PR may be reduced. This may represent the photoresist pattern being partially removed with the removal of the hard mask HM, the upper transparent layer TIL, and the upper transparent organic layer TOL.

The light blocking organic material BLD may be a material (photoresist) that causes chemical changes when irradiated with light.

The black pigment may contain a light blocking material, and examples of the light blocking material may include carbon black, carbon nanotubes, a resin or paste containing black dye, and metal particles—for example, nickel, aluminum, molybdenum, and alloys thereof, metal oxide particles (for example, chromium nitride) and so on.

A light blocking organic material BLD may contain a light blocking material, may have a black color, and may have characteristics of absorbing/blocking light rather than reflecting it.

If the light blocking organic material BLD may contain less than about 5% of solid components, the area where the hard mask HM, the upper transparent layer TIL, and the upper transparent organic layer TOL were removed can be readily filled, so that no voids that are not filled with the light blocking organic material BLD are formed.

Depending on the embodiment, the applied organic material BLD may be developed.

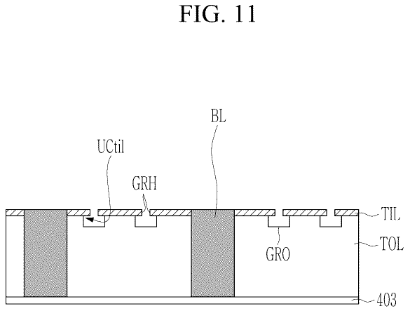

Afterwards, as shown in FIG. 11, the organic material BLD and photoresist pattern PR applied on the top may be removed through a dry ashing process over the entire area, and a hard mask HM may be applied to complete the light blocking linear pattern BL.

When removing the hard mask HM, the hard mask HM disposed in the groove GRO of the upper transparent organic layer TOL may be removed.

For this purpose, it may be removed using a wet etching method or a dry etching method.

In FIG. 6 to FIG. 11, a method of manufacturing the light blocking linear pattern BL, the upper transparent organic layer TOL, and the upper transparent layer TIL according to an embodiment is described in detail.

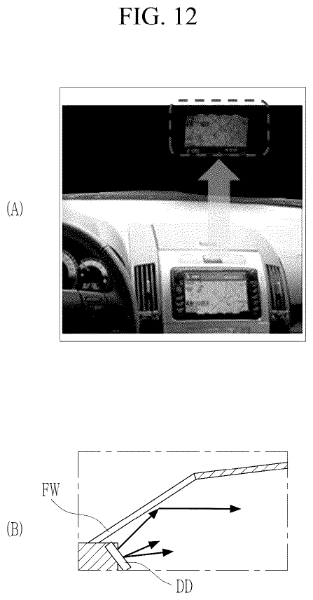

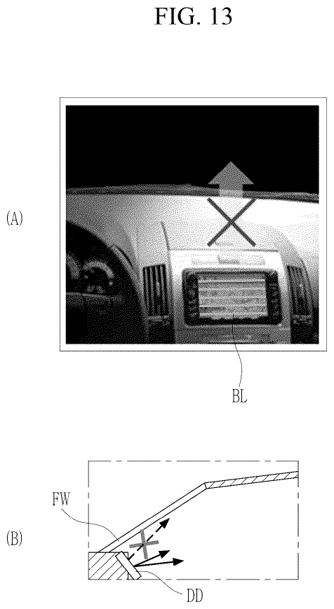

The effects that can be had in case that a display device having the structure described above and including a light blocking linear pattern BL formed through a manufacturing method is applied to a vehicle will be described through FIG. 13 while comparing it with the comparative example of FIG. 12.

FIG. 12 is a schematic diagram illustrating a case where a light emitting display device according to a comparative example is applied to a vehicle, and FIG. 13 is a schematic diagram illustrating a case where a light emitting display device according to an embodiment is applied to a vehicle.

In the comparative example of FIG. 12, the light emitting display device DD used in a vehicle may not include the light blocking linear pattern BL, and as shown in FIG. 12(B), the angle of the emitted light may not be limited and may be emitted in various directions.

In contrast, in the embodiment of FIG. 13, the light emitting display device DD used in a vehicle includes one or more light blocking linear patterns BL arranged in a direction (horizontal direction) to partially block light emitted in the vertical direction.

Light of more than 30 degrees based on the normal line perpendicular to the front of the light emitting display device DD may be blocked.

Referring to FIG. 12, the light emitted from the light emitting display device DD disposed in the center fascia portion of the vehicle may be also provided to a windshield FW of the vehicle, and at night, the light emitted from the light emitting display device DD, and as it reflects from the windshield FW, it may be transmitted to the driver's eyes, which may cause problems that interfere with the driver's field of vision.

In contrast, referring to FIG. 13, the light emitting display device DD used in a vehicle may have one or more light blocking linear patterns BL, so that the light emitted from the light emitting display device DD may be transmitted to the windshield FW of the vehicle, so that it does not reflect from the windshield FW even at night and does not interfere with the driver's view.

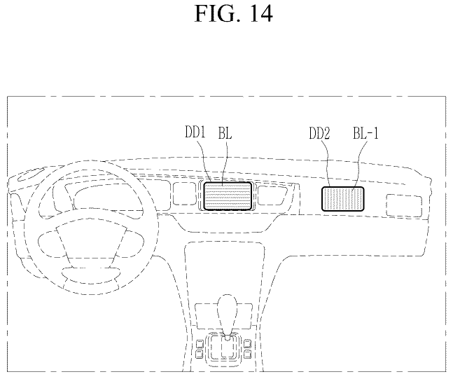

Depending on the embodiment, the arrangement direction of the light emitting display device DD and the light blocking linear patterns BL used in the vehicle may vary, and an embodiment of them will be described through FIG. 14.

FIG. 14 is a schematic diagram illustrating a case where a light emitting display device is applied to a vehicle according to another embodiment.

The vehicle according to the embodiment of FIG. 14 may be equipped with two light emitting display devices DD1 and DD2.

The first light emitting display device DD1 may be disposed in the center fascia as shown in FIG. 14 and may have one or more light blocking linear patterns BL arranged in the horizontal direction.

As a result, light may not be reflected on the windshield and may not interfere with the driver's vision.

The second light emitting display device DD2 may be disposed in front of the passenger seat and may have one or more light blocking linear patterns BL−1 arranged in the vertical direction.

Due to the light blocking linear patterns BL−1 arranged in the vertical direction, the light emitted from the second light emitting display device DD2 may not be provided in the left and right directions, so only the person sitting in the passenger seat can use the second light emitting display device DD2, and the driver cannot see the screen of the second light emitting display device DD2.

As a result, there is an advantage at least in that the driver can focus on driving without paying attention to the second light emitting display device DD2.

In FIG. 14, the first light emitting display device DD1 has multiple first light blocking linear patterns extending in the first direction, and has an upper transparent organic layer and an upper transparent layer in between, a hole is disposed in the upper transparent layer, and an undercut groove can be formed on the upper surface of the upper transparent organic layer at the position corresponding to the hole.

The second light emitting display device DD2 may have one or more second light blocking linear patterns extending in a second direction different from the first direction, and may have an upper transparent organic layer and an upper transparent layer between them, and the upper transparent layer may include a hole, and an undercut groove may be formed on the upper surface of the upper transparent organic layer at a position corresponding to the hole.

Depending on the embodiment, only one of the first light emitting display device DD1 and the second light emitting display device DD2 may have a display device having the structure described in FIG. 1 to FIG. 5, and the other one may include only a light blocking device extending in a direction.

In the above, the light blocking linear pattern BL and its surrounding structure and manufacturing method along with the schematic structure of the light emitting display device was described in detail.

Hereinafter, the structure of the light emitting diode disposed below the light blocking linear pattern BL will be described in more detail with reference to FIG. 15.

FIG. 15 is a schematic diagram illustrating a cross-sectional structure of a light emitting display device according to an embodiment.

FIG. 15 shows a stacked structure of pixels disposed in the display area of a light emitting display device.

The light emitting display device may be divided into a lower panel layer and an upper panel layer, the lower panel layer being where the light emitting diodes and pixel circuitry that make up the pixel are disposed, and may include an encapsulation layer 400 that covers it.

Here, the pixel circuitry (or pixel circuit unit or pixel circuit part) may include the second organic layer 182 and the third organic layer 183, and may refer to the lower part thereof, the light emitting diode may be the upper part of the third organic layer 183, and may be disposed at the bottom of the encapsulation layer 400.

The structure disposed on top of the encapsulation layer 400 may correspond to the upper panel layer, and one or more light blocking linear patterns BL may be included in the upper panel layer.

Depending on the embodiment, the third organic layer 183 may not be included.

Referring to FIG. 15, a metal layer BML may be disposed on the substrate 110.

The substrate 110 may include a material that has rigid properties and does not bend, such as glass, or may include a flexible material that can bend, such as plastic or polyimide.

In the case of a flexible substrate, as shown in FIG. 15, it may have a double-layer structure of polyimide and a barrier layer formed of an inorganic insulating material thereon.

The metal layer BML may be formed in a position that overlaps the channel of the driving transistor in the plane of the subsequent first semiconductor layer ACT(P—Si), and is also called a lower shielding layer.

The metal layer BML may include a metal or metal alloy such as copper (Cu), molybdenum (Mo), aluminum (Al), or titanium (Ti).

Here, the driving transistor may refer to a transistor that generates current to be transmitted to the light emitting diode.

A buffer layer 111 covering (or overlapping) the substrate 110 and the metal layer BML may be disposed on the substrate 110.

The buffer layer 111 may serve to block the penetration of impure elements into the first semiconductor layer ACT1(P—Si), and may be an inorganic insulating layer including, e.g., silicon oxide (SiOx), silicon nitride (SiNx), or silicon oxynitride (SiONx).

A first semiconductor layer ACT1 (P—Si) formed of a silicon semiconductor (e.g., polycrystalline semiconductor (P—Si)) is disposed on the buffer layer 111.

The first semiconductor layer ACT1(P—Si) may include a channel of a polycrystalline transistor LTPS TFT including a driving transistor, and a first region and a second region disposed on both sides of the channel.

Here, the polycrystalline transistor LTPS TFT may include various switching transistors as well as a driving transistor.

The first semiconductor layer ACT1(P—Si) may have regions on both sides of the channel that have conductive layer characteristics through plasma treatment or doping, and may serve as the first and second electrodes of the transistor.

A first gate insulating layer 141 may be disposed on the first semiconductor layer ACT1(P—Si).

The first gate insulating layer 141 may be an inorganic insulating layer containing, e.g., silicon oxide (SiOx), silicon nitride (SiNx), or silicon oxynitride (SiONx).

A first gate conductive layer including the gate electrode GAT1 of the polycrystalline transistor LTPS TFT may be disposed on the first gate insulating layer 141.

In addition to the gate electrode GAT1 of the polycrystalline transistor LTPS TFT, the first gate conductive layer may be formed with a scan line or an emission control line.

The first gate conductive layer may include a metal or metal alloy such as copper (Cu), molybdenum (Mo), aluminum (Al), or titanium (Ti), and may be composed of a single layer or multiple layers.

After forming the first gate conductive layer, a plasma treatment or doping process may be performed to make the exposed area of the first semiconductor layer conductive.

For example, the first semiconductor layer ACT1(P—Si) covered by the first gate conductive layer may not be conductive, and a portion of the first semiconductor layer ACT1(P—Si) not covered by the first gate conductive layer may have the same characteristics as the conductive layer.

A second gate insulating layer 142 may be disposed on the first gate conductive layer and the first gate insulating layer 141.

The second gate insulating layer 142 may be an inorganic insulating layer containing, e.g., silicon oxide (SiOx), silicon nitride (SiNx), or silicon oxynitride (SiONx).

A second gate conductive layer GAT2 that includes a first electrode GAT2(Cst) of a storage capacitor Cst and a lower shielding layer GAT2(BML) of an oxide transistor Oxide TFT may be disposed on the second gate insulating layer 142.

The lower shielding layer GAT2(BML) of the oxide transistor Oxide TFT may be disposed at the bottom of the channel of each oxide transistor Oxide TFT and may serve to shield against light or electromagnetic interference provided to the channel from the bottom.

An electrode GAT2(Cst) of the storage capacitor Cst may overlap the gate electrode GAT1 of the driving transistor to form the storage capacitor Cst.

Depending on the embodiment, the second gate conductive layer GAT2 may further include a scan line, a control line, or a voltage line.

The second gate conductive layer GAT2 may include a metal or metal alloy such as copper (Cu), molybdenum (Mo), aluminum (Al), or titanium (Ti), and may be composed of a single layer or multiple layers.

A first interlayer insulating layer 161 may be disposed on the second gate conductive layer GAT2.

The first interlayer insulating layer 161 may include an inorganic insulating layer containing silicon oxide (SiOx), silicon nitride (SiNx), or silicon oxynitride (SiONx), and depending on the embodiment, the inorganic insulating material may be formed in a thick layer.

An oxide semiconductor layer ACT2(IGZO), also referred to as a second semiconductor layer) including a channel, first region, and second region of an oxide transistor Oxide TFT may be disposed on the first interlayer insulating layer 161.

A third gate insulating layer 143 may be disposed on the oxide semiconductor layer ACT2(IGZO).

The third gate insulating layer 143 may be disposed on the entire surface of the oxide semiconductor layer ACT2(IGZO) and the first interlayer insulating layer 161.

The third gate insulating layer 143 may include an inorganic insulating layer containing silicon oxide (SiOx), silicon nitride (SiNx), or silicon oxynitride (SiONx).

A third gate conductive layer including the gate electrode GAT3 of an oxide transistor Oxide TFT may be disposed on the third gate insulating layer 143.

The gate electrode GAT3 of the oxide transistor Oxide TFT may overlap the channel.

The third gate conductive layer may further include a scan line or a control line.

The third gate conductive layer may contain a metal or metal alloy such as copper (Cu), molybdenum (Mo), aluminum (Al), or titanium (Ti), and may be composed of a single layer or multiple layers.

A second interlayer insulating layer 162 may be disposed on the third gate conductive layer.

The second interlayer insulating layer 162 may have a single-layer or multi-layer structure.

The second interlayer insulating layer 162 may include an inorganic insulating material such as silicon nitride (SiNx), silicon oxide (SiOx), or silicon oxynitride (SiOxNy), and may include an organic material depending on the embodiment.

A first data conductive layer SD1 may be disposed on the second interlayer insulating layer 162 and may include a connection electrode that can be connected to the first and second regions of each of the polycrystalline transistor LTPS TFT and the oxide transistor Oxide TFT.

The first data conductive layer SD1 may include a metal or metal alloy such as aluminum (Al), copper (Cu), molybdenum (Mo), or titanium (Ti), and may be composed of a single layer or multiple layers.

The first organic layer 181 may be disposed on the first data conductive layer SD1.

The first organic layer 181 may be an organic insulating layer containing an organic material, and the organic material includes one or more materials selected from the group consisting of polyimide, polyamide, acrylic resin, benzocyclobutene, and phenol resin.

A second data conductive layer including an anode connection electrode ACM2 may be disposed on the first organic layer 181.

The second data conductive layer may include a data line or a driving voltage line.

The second data conductive layer may contain a metal or metal alloy such as aluminum (Al), copper (Cu), molybdenum (Mo), or titanium (Ti), and may be composed of a single layer or multiple layers.

The anode connection electrode ACM2 may be connected to the first data conductive layer SD1 through the opening OP3 disposed in the first organic layer 181.

Above the second data conductive layer, the second organic layer 182 and the third organic layer 183, and an anode connection opening OP4 may be formed in the second organic layer 182 and the third organic layer 183.

The anode connection electrode ACM2 may be electrically connected to the anode through the anode connection opening OP4.

The second organic layer 182 and the third organic layer 183 may be organic insulating layers and may include one or more materials selected from the group consisting of polyimide, polyamide, acrylic resin, benzocyclobutene, and phenol resin.

Depending on the embodiment, the third organic layer 183 may be omitted.

A pixel defining layer 380 may be disposed on the anode, covering at least a portion of the anode and having an opening OP exposing the anode.

The pixel defining layer 380 may be a black pixel defining layer formed of a black organic material to prevent light applied from the outside from being reflected back to the outside, and depending on the embodiment, it may be formed of a transparent organic material.

Therefore, depending on the embodiment, the pixel defining layer 380 may include a negative-type black organic material and a black pigment.

A spacer 385 is disposed on the pixel defining layer 380.

Unlike the pixel defining layer 380, the spacer 385 may be formed of a transparent organic insulating material.

Depending on the embodiment, the spacer 385 may be formed of a positive-type transparent organic material.

The spacer 385 may include two parts 385-1 and 385-2 of different heights, with the high part 385-1 serving as a spacer and the low part 385-2 improving the adhesion characteristics between the spacer and the pixel defining layer 380.

A functional layer FL and a cathode may be sequentially formed on the anode, the spacer 385, and the pixel defining layer 380, and the functional layer FL and cathode may be formed over the entire area.

The light emitting layer EML may be disposed between the functional layers FL, and the light emitting layer EML may be disposed only within the opening OP of the pixel defining layer 380.

Hereinafter, the functional layer FL and the light emitting layer EML may be combined and referred to as the intermediate layer.

The functional layer FL may include at least one auxiliary layer such as an electron injection layer, an electron transport layer, a hole transport layer, and a hole injection layer, and the hole injection layer and the hole transport layer may be disposed below the light emitting layer EML, and an electron transport layer and an electron injection layer may be disposed on top of the light emitting layer EML.

The encapsulation layer 400 may be disposed on the cathode.

The encapsulation layer 400 may include at least one inorganic film and/or at least one organic film, and may have a triple-layer structure including a first inorganic encapsulation layer, an organic encapsulation layer, and a second inorganic encapsulation layer, as in the embodiment of FIG. 4.

The encapsulation layer 400 may be used to protect the light emitting layer EML from moisture or oxygen that may enter from the outside.

Depending on the embodiment, the encapsulation layer 400 may include a structure in which an inorganic layer and an organic layer are further sequentially stacked.

Sensing insulating layers 501, 510, 511 and one or more sensing electrodes 540, 541 may be disposed on the encapsulation layer 400 for touch detection.

In the embodiment of FIG. 15, touch may be sensed in a capacitive manner using two sensing electrodes 540 and 541.

Specifically, a first sensing insulating layer 501 may be formed on the encapsulation layer 400, and sensing electrodes 540 and 541 may be formed thereon.

The sensing electrodes 540 and 541 may be insulated with the second sensing insulating layer 510 disposed or interposed therebetween, and some of them may be electrically connected through an opening disposed in the sensing insulating layer 510.

The sensing electrodes 540 and 541 may be made of metal or metal alloy such as aluminum (Al), copper (Cu), silver (Ag), gold (Au), molybdenum (Mo), titanium (Ti), and tantalum (Ta), and they may include a single layer or multiple layers.

A third sensing insulating layer 511 may be formed on the sensing electrode 540.

Light blocking linear patterns BL may be formed on the third sensing insulating layer 511.

For example, the upper transparent organic layer TOL and the light blocking linear patterns BL may be disposed on the third sensing insulating layer 511, and the upper transparent organic layer TOL on which the plurality of light blocking linear patterns BL may not be disposed, the upper transparent layer TIL may be disposed.

One or more holes GRH may be disposed in the upper transparent layer TIL, and grooves GRO may be formed at positions corresponding to the holes GRH in the upper transparent organic layer TOL.

Due to the light blocking linear patterns BL, a separate light blocking member, color filter, and/or color conversion layer may not be formed.

However, depending on the embodiment, if necessary, it may be additionally formed on the top or bottom of the light blocking linear patterns BL.

Additionally, depending on the embodiment, a polarizer may be included on top of the light blocking linear patterns BL.

However, in an embodiment in which the pixel defining layer 380 is formed to include black pigment, a polarizer may not be used.

The light blocking linear patterns BL and the upper transparent layer TIL may be covered with an additional organic layer (also called a planarization layer) to flatten the entire surface of the light emitting display device.

In FIG. 15, an embodiment in which a total of three organic layers are formed and an anode connection opening is formed in the second organic layer and the third organic layer is described.

However, at least two organic layers may be formed, and in this case, the anode connection opening may be disposed in the upper organic layer disposed away from the substrate, and the lower organic layer opening may be disposed in the lower organic layer.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device, comprising:
a light emitting diode disposed on a substrate and including a light emitting layer;
a pixel defining layer having an opening corresponding to the light emitting layer;
a plurality of light blocking linear patterns disposed on the pixel defining layer and the light emitting layer and extending in a direction;
an upper transparent organic layer disposed between adjacent ones of the plurality of light blocking linear patterns; and
an upper transparent layer disposed on the upper transparent organic layer and having a plurality of holes overlapping the upper transparent organic layer.

2. The display device of claim 1, wherein a plurality of grooves are formed on an upper surface of the upper transparent organic layer at positions corresponding to each of the plurality of holes.

3. The display device of claim 2, wherein each of the plurality of grooves has an undercut structure and is formed larger than each of the plurality of holes.

4. The display device of claim 3, wherein the upper transparent layer is formed of a transparent conductive oxide.

5. The display device of claim 4, wherein
each of the plurality of light blocking linear patterns has a height of about 20 μm or more and about 50 μm or less, and a width of about 1 μm or more and about 7 μm or less, and
each of the plurality of grooves has a depth of about 0.9 μm or more and about 10 μm or less.

6. The display device of claim 4, wherein the plurality of holes have an area ratio in a range of about 10% to about 20% of a total area.

7. The display device of claim 1, wherein at least one of the plurality of light blocking linear patterns crosses and overlaps the light emitting layer.

8. The display device of claim 1, wherein the upper transparent layer and the upper transparent organic layer do not overlap the plurality of light blocking linear patterns.

9. A method of manufacturing a display device, comprising:
continuously forming an upper transparent organic layer and an upper transparent layer on a substrate having an encapsulation layer;
forming a plurality of holes by etching the upper transparent layer;
forming a hard mask on the upper transparent layer;
forming a photoresist pattern on the hard mask and removing exposed the hard mask, the upper transparent layer, and the upper transparent organic layer using the photoresist pattern as a mask to form a portion where a light blocking linear pattern is to be formed;
applying a light blocking organic material containing a black pigment; and
removing the photoresist pattern and the light blocking organic material applied on a top portion and removing the hard mask to complete the light blocking linear pattern.

10. The method of manufacturing a display device of claim 9, wherein the forming of the plurality of holes includes etching the upper transparent organic layer exposed by the plurality of holes of the upper transparent layer together to form a plurality of grooves on an upper surface of the upper transparent organic layer.

11. The method of manufacturing a display device of claim 10, wherein each of the plurality of grooves has an undercut structure and is formed larger than each of the plurality of holes.

12. The method of manufacturing a display device of claim 11, wherein each of the plurality of grooves is formed deeper than a thickness of the hard mask by at least about 0.1 μm and no more than about 5 km.

13. The method of manufacturing a display device of claim 12, wherein
the light blocking linear pattern has a height of about 20 μm or more and about 50 μm or less, and a width of about 1 μm or more and about 7 μm or less, and
each of the plurality of grooves has a depth of about 0.9 μm or more and about 10 μm or less.

14. The method of manufacturing a display device of claim 12, wherein the plurality of holes have an area ratio in a range of about 10% to about 20% of a total area.

15. A vehicle, comprising:
a first light emitting display device comprising:
a light emitting diode disposed on a substrate and including a light emitting layer;
a pixel defining layer having an opening corresponding to the light emitting layer;
a plurality of first light blocking linear patterns disposed on the pixel defining layer and the light emitting layer and extending in a first direction;
an upper transparent organic layer disposed between adjacent ones of the plurality of first light blocking linear patterns; and
an upper transparent layer disposed on the upper transparent organic layer and having a plurality of holes overlapping the upper transparent organic layer.

16. The vehicle of claim 15, further comprising:
a second light emitting display device comprising
a light emitting diode disposed on a substrate and including a light emitting layer;
a pixel defining layer having an opening corresponding to the light emitting layer; and
a plurality of second light blocking linear patterns disposed on the pixel defining layer and the light emitting layer and extending in a second direction different from the first direction;
an upper transparent organic layer disposed between adjacent ones of the plurality of second light blocking linear patterns; and
an upper transparent layer disposed on the upper transparent organic layer and having a plurality of holes overlapping the upper transparent organic layer.

17. The vehicle of claim 16, wherein a plurality of grooves are formed on an upper surface of the upper transparent organic layer at positions corresponding to each of the plurality of holes.

18. The vehicle of claim 17, wherein each of the plurality of grooves has an undercut structure and is formed larger than each of the plurality of holes.

19. The vehicle of claim 18, wherein the upper transparent layer is formed of a transparent conductive oxide.

20. The vehicle of claim 19, wherein
each of the plurality of first light blocking linear patterns or each of the plurality of second light blocking linear patterns has a height of about 20 μm or more and about 50 μm or less, and a width of about 1 μm or more and about 7 μm or less,
each of the plurality of grooves has a depth of about 0.9 μm or more and about 10 μm or less, and
the plurality of holes have an area ratio in a range of about 10% to about 20% of a total area.
